(19) United States
(12) Patent Application Publication
(10) Pub. No.: US 2026/0096235 A1
(43) Pub. Date: Apr. 2, 2026

(54) IMAGE SENSOR

(71) Applicant: Samsung Electronics Co., Ltd., Suwon-si (KR)

(72) Inventor: Sangchul SUL, Suwon-si (KR)

(73) Assignee: Samsung Electronics Co., Ltd., Suwon-si (KR)

(21) Appl. No.: 19/073,689

(22) Filed: Mar. 7, 2025

(30) Foreign Application Priority Data
Sep. 27, 2024 (KR) 10-2024-0131516

(51) Int. Cl. H10F 39/00; H10F 39/10; H10K 39/32

(52) U.S. Cl. CPC H10F 39/806; H10F 39/103; H10F 39/811; H10K 39/32

(57) ABSTRACT

An image sensor includes a first photo detector (PD) in a substrate, the first PD absorbing a visible ray; a spacer layer on the substrate; a nano-prism on the spacer layer; and a second PD structure on the nano-prism, the second PD structure absorbing an infrared ray. The nano-prism divides an incident light into a plurality of lights by color, and the spacer layer condenses each of the plurality of lights into the first PD. The nano-prism includes a first low refractive layer and a first nano-post pattern extending through the first low refractive layer.

### CROSS-REFERENCE TO RELATED APPLICATION

This application claims priority under 35 USC § 119 to Korean Patent Application No. 10-2024-0131516, filed on Sep. 27, 2024, in the Korean Intellectual Property Office (KIPO), the contents of which are herein incorporated by reference in their entirety.

### BACKGROUND

Some example embodiments of the present disclosure relate to image sensors.

To increase the sensitivity of image sensors, methods have been developed to absorb not only visible rays but also infrared rays and to utilize both the visible and infrared rays.

### SUMMARY

Some example embodiments of the present disclosure provide an image sensor having improved characteristics.

Some example embodiments provide an image sensor that includes a first photo detector (PD) in a substrate, the first PD absorbing a visible ray; a spacer layer on the substrate; a nano-prism on the spacer layer; and a second PD structure on the nano-prism, the second PD structure absorbing an infrared ray. The nano-prism divides an incident light into a plurality of lights by color, and the spacer layer condenses each of the plurality of lights onto the first PD. The nano-prism includes a first low refractive layer, and a first nano-post pattern extending through the first low refractive layer.

Some example embodiments further provide an image sensor that includes a first photo detector (PD) in a substrate, the first PD absorbing a visible ray; a second PD structure on the substrate, the second PD structure absorbing an infrared ray; and a nano-prism on the second PD structure. The nano-prism includes a low refractive layer, and nano-post patterns in the low refractive layer, the nano-post patterns being spaced apart from each other in a horizontal direction, and diameters of nano-post patterns being different from each other.

Some example embodiments still further provide an image sensor that includes first and second wiring structures under a substrate; a first floating diffusion (FD) region at a lower portion of the substrate, the first FD region being electrically connected to the first wiring structure; a first photo detector (PD) in a substrate, the first PD absorbing a visible ray; a second FD region at the lower portion of the substrate, the second FD region being electrically connected to the second wiring structure; a spacer layer on the substrate; a nano-prism on the spacer layer; a second PD structure on the nano-prism, the second PD structure absorbing an infrared ray; and a through via structure extending through the substrate, the spacer layer and the nano-prism, the through via structure being electrically connected to the second wiring structure and the second PD structure.

In image sensor in accordance with some example embodiments of the present disclosure, the first photo detector absorbing a visible ray and the second photo detector absorbing an infrared ray may be arranged in the vertical direction, and thus the image sensor may have enhanced sensitivity.

### BRIEF DESCRIPTION OF THE DRAWINGS

FIG. 1 is a cross-sectional view illustrating an image sensor in accordance with some example embodiments.

FIG. 2 is a plan view illustrating a layout of nano-post patterns included in a nano-prism of the image sensor of FIG. 1.

FIGS. 3, 4, 5, 6, 7 and 8 are cross-sectional views illustrating a method of manufacturing an image sensor in accordance with some example embodiments.

FIGS. 9, 10, 11 and 12 are cross-sectional views illustrating image sensors in accordance with some example embodiments.

FIG. 13 is a plan view illustrating a layout of nano-post patterns included in a nano-prism of an imager sensor in accordance with some example embodiments.

### DESCRIPTION

Image sensors and methods of manufacturing the same in accordance with some example embodiments of the inventive concepts will be more clearly understood from the following detailed description taken in conjunction with the accompanying drawings.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of the inventive concepts.

Hereinafter, two directions among horizontal directions that are substantially parallel to an upper surface of each of first and second substrates, which may intersect each other, may be referred to as first and second directions D1 and D2, respectively, and a vertical direction that is substantially perpendicular to the upper surface of each of first and second substrates may be referred to as a third direction D3. Each of the first to third directions D1, D2 and D3 may include not only a direction shown in the drawings but also an inverse direction thereto. In some example embodiments, the first and second directions D1 and D2 may be substantially perpendicular to each other.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

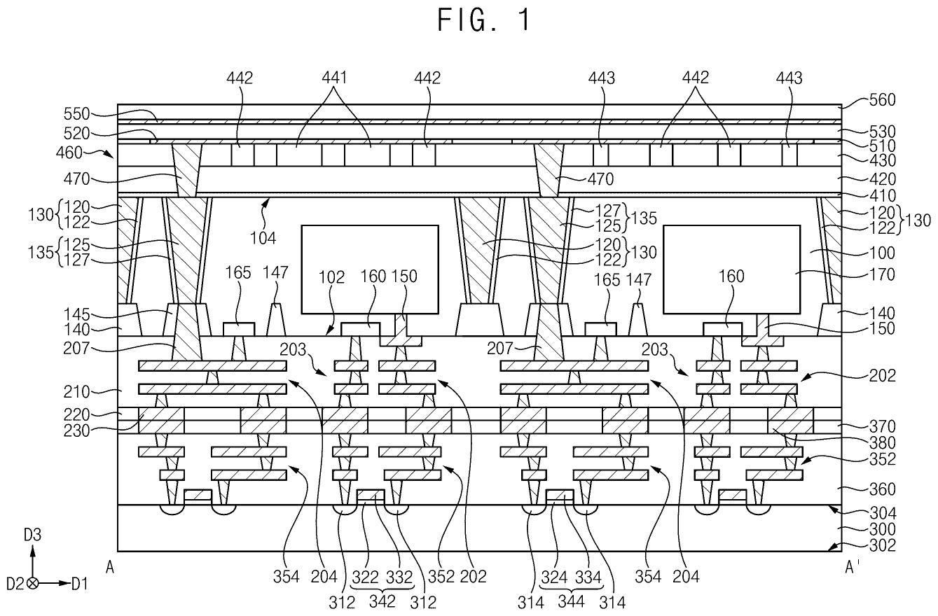

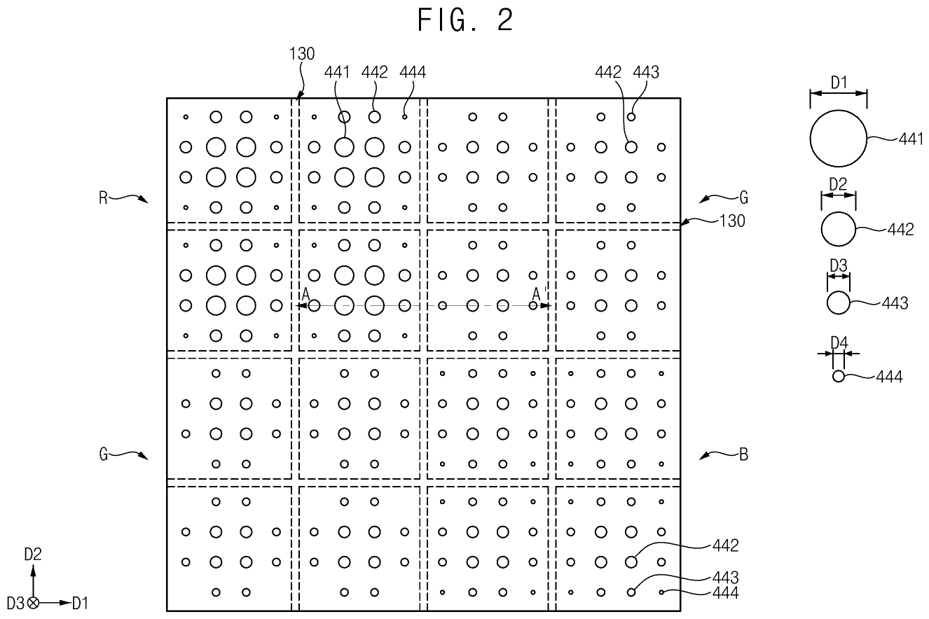

FIG. 1 is a cross-sectional view illustrating an image sensor in accordance with some example embodiments. FIG. 2 is a plan view illustrating a layout of nano-post patterns included in a nano-prism of the image sensor of FIG. 1. FIG. 1 is a cross-sectional view taken along line A-A′ of FIG. 2.

Referring to FIGS. 1 and 2, the image sensor may include transistors, fourth and fifth wiring structures 352 and 354, a second insulating interlayer 360, first and second bonding layers 220 and 370, first to third wiring structures 202, 203 and 204, a first insulating interlayer 210, a transfer gate (TG) 150, a first substrate 100, a first buffer layer 410, a spacer layer 420, a nano-prism 460, a first electrode layer 510, a second photo detector (PD) 530, a second electrode 550 and a first protective layer 560 on a second substrate 300.

The image sensor may further include first and second floating diffusion (FD) regions 160 and 165 and a first photo detector (PD) 170 that may be disposed in the first substrate 100, first and second division patterns 130 and 140, fourth and fifth insulation patterns 145 and 147 and a first through via 135 that may partially extend through the first substrate 100, and a third through via 470 that may extend through the first buffer layer 410, the spacer layer 420 and the nano-prism 460.

In some example embodiments, the image sensor may further include a third substrate on which an image signal processor (ISP) including, e.g., analog digital converter (ADC) circuit is disposed bonded to the second substrate 300 under the second substrate 300.

The second substrate 300 may include first and second surfaces 302 and 304 opposite to each other in the third direction D3. FIG. 1 shows that the first surface 302 is a lower surface of the second substrate 300 and the second surface 304 is an upper surface of the second substrate 300. The second substrate 300 may include a semiconductor material such silicon, germanium, silicon-germanium, etc., or a III-V group compound, such as GaP, GaAs, or GaSb.

Each of the transistors may include a gate structure on the second surface 304 of the second substrate 300, and source/drain regions at respective upper portions of the second substrate 300 adjacent to the gate structure. In some example embodiments the transistors my include, e.g., source follower (SF) transistor, a select transistor and a reset transistor.

FIG. 1 shows first and second transistors as the transistors. The first transistor may include a first gate structure 342 on the second substrate 300 and first impurity regions 312 at respective upper portions of the second substrate 300 adjacent to the first gate structure 342, and the second transistor may include a second gate structure 344 on the second substrate 300 and second impurity regions 314 at respective upper portions of the second substrate 300 adjacent to the second gate structure 344. The first gate structure 342 may include a first gate insulation pattern 322 and a first gate electrode 332 stacked in the third direction D3, and the second gate structure 344 may include a second gate insulation pattern 324 and a second gate electrode 334 stacked in the third direction D3.

Each of the first and second gate insulation patterns 322 and 324 may include an oxide, e.g., silicon oxide, and each of the first and second gate electrodes 332 and 334 may include a conductive material, e.g., a metal, a metal nitride, a metal silicide, etc. Each of the first and second impurity regions 312 and 314 may include, e.g., n-type impurities or p-type impurities.

The fourth and fifth wiring structures 352 and 354 may be disposed on the second substrate 300, and may be electrically connected to the first and second transistors, respectively. Each of the fourth and fifth wiring structures 352 and 354 may include, e.g., contact plugs, wirings, vias, etc., which may include a conductive material, e.g., a metal, a metal nitride, a metal silicide, etc.

The second insulating interlayer 360 may be disposed on the second substrate 300, and may cover the fourth and fifth wiring structures 352 and 354. The second insulating interlayer 360 may include, e.g., silicon oxide, a low-k dielectric material, etc.

The second bonding layer 370 may be disposed on the second insulating interlayer 360, and may include a second bonding pad 380 extending through the second bonding layer 370. The first bonding layer 220 may be disposed on and bonded to the second bonding layer 370, and may include a first bonding pad 230 extending through the first bonding layer 220. The bonded first and second bonding layers 220 and 370 may collectively form a bonding layer structure. In some example embodiments, a plurality of first bonding pads 230 may be spaced apart from each other in the horizontal direction in the first bonding layer 220, and a plurality of second bonding pads 380 may be spaced apart from each other in the horizontal direction in the second bonding layer 370. The first and second bonding pads 230 and 380 may contact each other, and may collectively form a bonding pad structure.

Thus, a plurality of bonding pad structures may be spaced apart from each other in the horizontal direction in the bonding layer structure, and each of the bonding pad structures may be electrically connected to a corresponding one of the fourth and fifth wiring structures 352 and 354.

Each of the first and second bonding layers 220 and 370 may include, e.g., silicon carbonitride, silicon oxide, etc., and each of the first and second bonding pads 230 and 380 may include a metal, e.g., copper.

Each of the first to third wiring structures 202, 203 and 204 may be disposed on the bonding layer structure, and may contact a corresponding one of the bonding pad structures to be electrically connected thereto.

Each of the first to third wiring structures 202, 203 and 204 may include, e.g., contact plugs, wirings, vias, etc., which may include a conductive material, e.g., a metal, a metal nitride, a metal silicide, etc. The third wiring structure 204 may further include a second through via 207.

The first insulating interlayer 210 may be disposed on the bonding layer structure, and may cover the first to third wiring structures 202, 204 and 205. The first insulating interlayer 210 may include, e.g., silicon oxide, a low-k dielectric material, etc.

The first substrate 100 may include first and second surfaces 102 and 104 opposite to each other in the third direction D3. FIG. 1 shows that the first surface 102 of the first substrate 100 is a lower surface thereof and the second surface 104 is an upper surface thereof. The first substrate 100 may include a semiconductor material such silicon, germanium, silicon-germanium, etc., or a III-V group compound, such as GaP, GaAs, or GaSb. In some example embodiments, a p-type well including p-type impurities may be formed in a portion or an entire portion of the first substrate 100.

The first division pattern 130 may extend through a portion of the first substrate 100 adjacent to the second surface 104, for example through an upper portion of the first substrate 100, and the second division pattern 140 may extend through a portion of the first substrate 100 adjacent to the first surface 102, for example through a lower portion of the first substrate 100, to contact a lower surface of the first division pattern 130. Thus, the second division pattern 140 and the first division pattern 130 stacked in the third direction D3 may extend through the first substrate 100, and may collectively form a division pattern structure.

In some example embodiments, the division pattern structure may have, e.g., a lattice shape in a plan view, and thus the first substrate 100 may be divided into a plurality of unit pixel regions by the division pattern structure. However, the unit pixel region may also be defined in a portion of each of the first buffer layer 410, the spacer layer 420, the nano-prism 460, the first electrode layer 510, the second PD 530, the second electrode 550 and the first protective layer 560 corresponding to the unit pixel region in the first substrate 100. Further, the unit pixel region may also be defined not only in an inside of the first substrate 100 but also spaces over and under the first substrate 100 in the third direction D3 and structures disposed in the spaces.

In some example embodiments, the first division pattern 130 may have a width gradually decreasing from a top toward a bottom thereof, and the second division pattern 140 may have a width gradually increasing from a top toward a bottom thereof. In some example embodiments, a width of an upper surface of the second division pattern 140 may be greater than a width of a lower surface of the first division pattern 130. A length in the third direction D3 of the first division pattern 130 may be greater than a length in the third direction D3 of the second division pattern 140.

In some example embodiments, the first division pattern 130 may include a first conductive pattern 120 and a first insulation pattern 122 covering a sidewall of the first conductive pattern 120. The first conductive pattern 120 may include a metal, e.g., copper, tungsten, etc., or doped polysilicon, and the first insulation pattern 122 may include a metal oxide, e.g., aluminum oxide, tantalum oxide, etc., or silicon oxide.

The second division pattern 140 may include an oxide, e.g., silicon oxide.

Each of the fourth and fifth insulation patterns 145 and 147 may extend through the portion of the first substrate 100 adjacent to the first surface 102, that is, the lower portion of the first substrate 100 in each unit pixel region. In some example embodiments, each of the fourth and fifth insulation patterns 145 and 147 may have a width gradually increasing from a top toward a bottom thereof. In some example embodiments, a height of an upper surface of each of the fourth and fifth insulation patterns 145 and 147 may be the same or substantially the same as a height of the upper surface of the second division pattern 140.

Each of the fourth and fifth insulation patterns 145 and 147 may include an oxide, e.g., silicon oxide.

The first through via 135 may extend through the portion of the first substrate 100 adjacent to the second surface 104, for example through the upper portion of the first substrate 100 in each unit pixel region, and may contact the upper surface of the fourth insulation pattern 145. In some example embodiments, the first through via 135 may have a width gradually decreasing from a top toward a bottom thereof. In some example embodiments, a width of a lower surface of the first through via 135 may be smaller than a width of the upper surface of the fourth insulation pattern 145. A length in the third direction D3 of the first through via 135 may be greater than a length in the third direction D3 of the fourth insulation pattern 145.

In some example embodiments, the first through via 135 may include a second conductive pattern 125 and a second insulation pattern 127 covering a sidewall of the second conductive pattern 125. The second conductive pattern 125 may include a metal, e.g., copper, tungsten, etc., or doped polysilicon, and the second insulation pattern 127 may include a metal oxide, e.g., aluminum oxide, tantalum oxide, etc., or silicon oxide. In some example embodiments, the second conductive pattern 125 and the second insulation pattern 127 may include the same or substantially the same materials as the first conductive pattern 120 and the first insulation pattern 122, respectively.

The second through via 207 may extend through an upper portion of the first insulating interlayer 210 in each unit pixel region, and may contact a lower surface of the first through via 135. The second through via 207 may also extend through the fourth insulation pattern 145. In some example embodiments, the second through via 207 may have a width gradually increasing from a top toward a bottom thereof. The second through via 207 may include a metal, e.g., copper, tungsten, etc., or doped polysilicon.

The TG 150 may include a buried portion, which may extend in the third direction D3 through the portion of the first substrate 100 adjacent to the first surface 102, for example through the lower portion of the first substrate 100, and a protrusion portion, which may be disposed beneath the buried portion, have a lower surface lower than the first surface 102 of the first substrate 100, and contact the first surface 102 of the first substrate 100, in each unit pixel region. The TG 150 may include a metal, e.g., copper, tungsten, etc., or doped polysilicon.

The first FD region 160 may be disposed at a lower portion of the first substrate 100 adjacent to the TG 150 in each unit pixel region, and the second FD region 165 may be disposed at a lower portion of the first substrate 100 adjacent to the fourth insulation pattern 145. Each of the first and second FD regions 160 and 165 may include silicon doped with, e.g., n-type impurities.

The first PD 170 may be disposed in the inside of the first substrate 100 in each unit pixel region, and may contact or may be disposed adjacent to an upper surface of the buried portion of the TG 150. The first PD 170 may include silicon doped with, e.g., n-type impurities, and the first PD 170 and the p-type well in the first substrate 100 may collectively form an PN junction diode. Thus, the first PD 170 may also be referred to as a first photo diode, or a silicon photo diode because the first PD 170 may include doped polysilicon.

The TG 150, the first PD 170 and the first FD region 160 may collectively form a transfer transistor.

The first buffer layer 410 may be disposed on the second surface 104 of the first substrate 100, an upper surface of the first division pattern 130 and an upper surface of the first through via 135. The first buffer layer 410 may include an oxide, e.g., silicon oxide, and in some example embodiments, the image sensor may not include the first buffer layer 410.

The spacer layer 420 may be disposed on the first buffer layer 410. The spacer layer 420 may include an oxide, e.g., silicon oxide, and in some example embodiments, the spacer layer 420 may be merged with the first buffer layer 410.

In some example embodiments, the spacer layer 420 may have such a large thickness in the third direction D3 that a light having penetrated through the nano-prism 460 may be condensed to the first PD 170. Thus, the thickness in the third direction D3 of the spacer layer 420 may have a range the same or substantially the same as or wider than a wavelength range of a visible ray. For example, the thickness in the third direction D3 of the spacer layer 420 may be in a range of about 200 nm to about 1000 nm, preferably, in a range of about 400 nm to about 700 nm.

The nano-prism 460 may be disposed on the spacer layer 420, and may include a first low refractive layer 430 and a high refractive pattern extending through the first low refractive layer 430. The first low refractive layer 430 may include a material having a refractive index equal to or less than about 2, e.g., silicon oxide. The high refractive pattern may include a material more than about 2, e.g., titanium oxide. The high refractive pattern may also be referred to as a nano-post pattern, and the nano-prism 460 may also be referred to as a meta prism.

In some example embodiments, the nano-prism 460 may include a plurality of nano-post patterns having different diameters, which may be spaced apart from each other in the horizontal direction with various layouts.

FIG. 2 shows first to fourth nano-post patterns 441, 442, 443 and 444. In some example embodiments, each of the first to fourth nano-post patterns 441, 442, 443 and 444 may have a pillar shape, and may have a shape of, e.g., a circle, an ellipse, a polygon, a polygon with rounded corners, etc., in a plan view. The first to fourth nano-post patterns 441, 442, 443 and 444 may have first to fourth diameters D1, D2, D3 and D4, respectively, which may have decreasing values in this order.

In some example embodiments, some or all of the first to fourth nano-post patterns 441, 442, 443 and 444 may be spaced apart from each other in each of the first and second directions D1 and D2 in the first low refractive layer 430 in each unit pixel region, and an incident light may be diffracted according to the layout of the first to fourth nano-post patterns 441, 442, 443 and 444, and a light in a specific wavelength range, e.g., a red light R, a green light G and a blue light B may be filtered.

For example, the first, second and fourth nano-post patterns 441, 442 and 444 may be arranged in a first unit pixel region, the second and third nano-post patterns 442 and 443 may be arranged in a second unit pixel region, and the second, third and fourth nano-post patterns 442, 443 and 444 may be arranged in a third unit pixel region. Portions of the nano-prism 460 in the first to third unit pixel regions, respectively, may filter the red light R, the green light G and the blue light B, respectively.

In some example embodiments, the first nano-post patterns 441 may be disposed at a central portion of the first unit pixel region, the second nano-post patterns 442 may be disposed at edge portions of the first unit pixel region at opposite sides, respectively, of the first nano-post patterns 441 in each of the first and second directions D1 and D2, and the fourth nano-post patterns 444 may be disposed at four corner portions, respectively, of the first unit pixel region.

The second nano-post patterns 442 may be disposed at a central portion of the second unit pixel region, and the third nano-post patterns 443 may be disposed at edge portions of the second unit pixel region at opposite sides, respectively, of the second nano-post patterns 442 in each of the first and second directions D1 and D2.

Furthermore, the second nano-post patterns 442 may be disposed at a central portion of the third unit pixel region, the third nano-post patterns 443 may be disposed at edge portions of the third unit pixel region at opposite sides, respectively, of the second nano-post patterns 442 in each of the first and second directions D1 and D2, and the fourth nano-post patterns 444 may be disposed at four corner portions, respectively, of the third unit pixel region.

However, the above layout of the nano-post patterns is non-limiting, and the nano-prism 460 may include nano-post patterns disposed in other layouts.

FIG. 2 shows that four unit pixel regions adjacent to each other in the first and second directions D1 and D2 form a unit pixel region group, which may filter a light having the same wavelength range (Quad Bayer pattern array), however, the inventive concepts are not limited thereto.

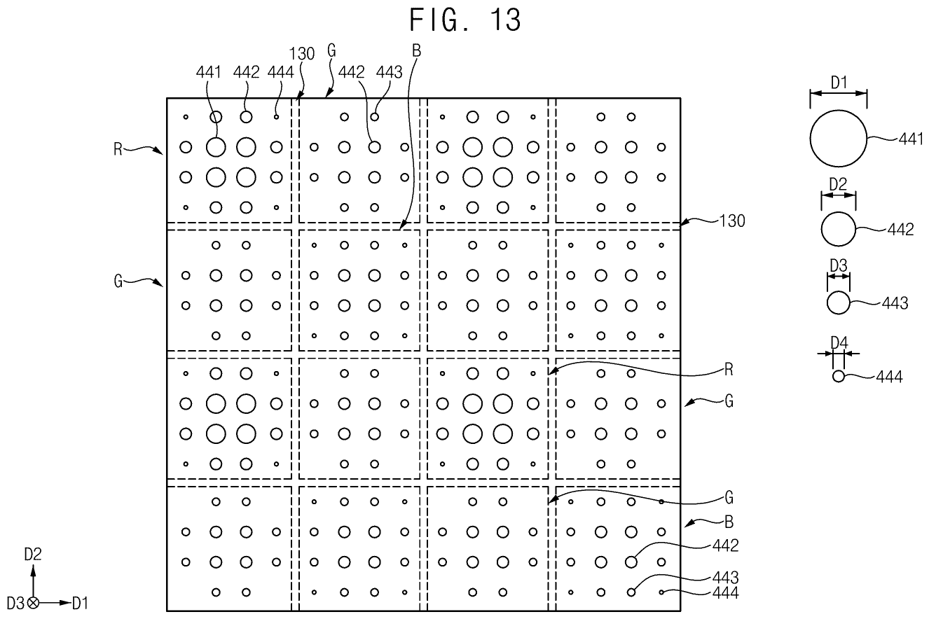

With reference to FIGS. 1 and 2 taken together with FIG. 13, for example, the first to fourth nano-post patterns 441, 442, 443 and 444 may be arranged such that light having different wavelength ranges from each other, e.g., the red light R, the green light G and the blue light B may be filtered by the unit pixel regions, respectively (Bayer pattern array).

The third through via 470 may extend through the first buffer layer 410, the spacer layer 420 and the first low refractive layer 430, and may contact an upper surface of the first through via 135 in each unit pixel region. The second through via 207, the first through via 135 and the third through via 470 sequentially stacked in the third direction D3 may collectively form a through via structure.

The first electrode layer 510 may be disposed on the nano-prism 460 and the third through via 470, and may include a first electrode 520 therein. The first electrode 520 may be disposed in each unit pixel region, and may contact an upper surface of the third through via 470.

The second PD 530 may be disposed on the first electrode layer 510.

In some example embodiments, the second PD 530 may include an active layer, an electron transport layer (ETL) on an upper surface of the active layer, and a hole transport layer (HTL) on a lower surface of the active layer. In some example embodiments, the active layer may have a bulk heterojunction (BHJ) structure in which a donor layer and an acceptor layer are interpenetrated with each other. Alternatively, the active layer may have a planar heterojunction (PHJ) structure in which a donor layer and an acceptor layer are stacked in a vertical direction.

The donor layer may include a thiopene-based polymer, e.g., P3HT (Poly(3-hexylthiophene)), and the acceptor layer may include a fullerene-based polymer. Thus, the second PD 530 may include an organic material, and the may be referred to as an organic photo detector or an organic photo diode, or a second photo diode.

Alternatively, the second PD 530 may be a quantum dot photo detector including a quantum dot (QD) of several nanometers. The QD may have a core including, e.g., cadmium selenide (CdSe), a shell surrounding the core and including, e.g., zinc sulfide (ZnS), and a coating layer covering a surface of the shell and including, e.g., trioctylphosphine (TOPO) oxide.

The second electrode 550 may be disposed on the second PD 530.

Each of the first and second electrodes 520 and 550 may be a transparent electrode including, e.g., indium tin oxide (ITO), indium zinc oxide (IZO), etc.

The first protective layer 560 may be disposed on and cover the second electrode 550. The first protective layer 560 may include a metal oxide, e.g., aluminum oxide.

The first electrode layer 510, the second PD 530, the second electrode 550 and the first protective layer 560 stacked in the third direction D3 may be collectively referred to as a second photo detector structure, an organic photo detector structure, an organic photo diode structure, etc., or a QD photo detector structure, a QD photo diode structure, etc.

When a light is incident onto an upper surface of the image sensor, that is, the second photo detector structure, a near infrared (NIR) ray of the light may be absorbed by the second PD 530 including an organic material. For example, the NIR ray may be absorbed by the active layer of the second PD 530 to generate an exiton, which may be divided into a hole and an electron to move to an anode and a cathode, respectively, between the first and second electrodes 520 and 550, through the HTL and the ETL, respectively. The electron or the hole moving to the first electrode 520 may move into and be stored in the second FD region 165 through the through via structure, for example through the first to third through vias 135, 207 and 470 and a portion of the third wiring structure 204.

If the second PD 530 is a QD photo detector, a short-wave infrared (SWIR) ray of the light may be absorbed by the second PD 530, and an electron or a hole generated by the SWIR ray may move into and be stored in the second FD region 165.

After the light passes through the second photo detector structure, other portions of the light other than for the NIR ray and the SWIR ray, for example a visible ray, may be divided into a red light R, a green light G and a blue light B when passing through the nano-prism 460, and each of the divided lights may pass through the spacer layer 420, the first buffer layer 410 and an upper portion of the first substrate 100 to be condensed into the first PD 170 so that electrons and holes may be generated. The electrons and the holes generated by the first PD 170 may move into and be stored in the first FD region 160.

Likewise, the NIR ray or the SWIR ray of the light incident onto the image sensor may be absorbed by the second PD 530, and the visible ray may be absorbed by the first PD 170, and thus, when compared to an image sensor having the first and second PDs 170 and 530 in the same level in the unit pixel region, the image sensor may have twice the sensitivity. For example, the image sensor may have increased sensitivity even with the unit pixel region having the same area.

The image sensor may include the nano-prism 460 and the spacer layer 420 between the first and second PDs 170 and 530, and the incident light may be divided by color, and each of the divided lights may be condensed into the first PD 170.

If, for example, the image sensor includes a micro lens and a color filter array, a light incident onto the image sensor may be condensed by the micro lens, and the condensed light may be divided into a red light R, a green light G and a blue light B by the color filter array. Thus, only one-third of the total light may be incident onto a photo detector in each unit pixel region so that about two-thirds of light may be lost.

However, in some example embodiments, the image sensor may include the nano-prism 460 and the spacer layer 420 instead of the micro lens and the color filter array, and after the light is divided into the red light R, the green light G and the blue light B through the nano-prism 460, lights having the same color may be condensed incident into the first PD 170 through portions of the spacer layer 420 not only in a unit pixel region but also in ones of the unit pixel regions adjacent thereto. Accordingly, the image sensor may further have increased sensitivity.

As the image sensor has the increased sensitivity, for example, an image sensor for vehicles, which may be used in environments with varying light intensity, such as an exit of a dark tunnel or an underground parking lot, may have improved features.

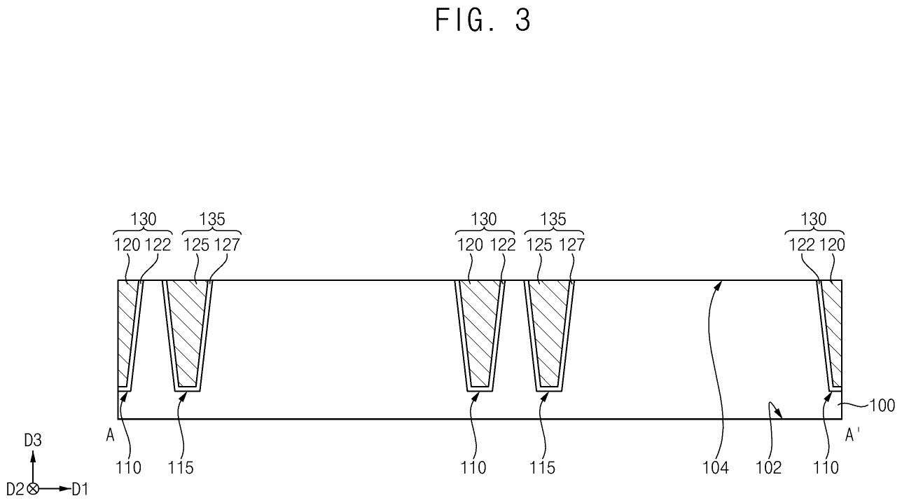

FIGS. 3 to 8 are cross-sectional views illustrating a method of manufacturing an image sensor in accordance with some example embodiments, which may be cross-sectional views taken along line of FIG. 2.

Referring to FIG. 3, a portion of a first substrate 100 including first and second surfaces 102 and 104 opposite to each other in the third direction D3, which may be adjacent to the second surface 104, may be removed to form first and second trenches 110 and 115, a first insulation layer may be formed on inner walls of the first and second trenches 110 and 115 and the second surface 104 of the first substrate 100, a first conductive layer may be formed on the first insulation layer to fill the first and second trenches 110 and 115, and a planarization process, e.g., a chemical mechanical polishing (CMP) process may be performed on the first conductive layer and the first insulation layer until the second surface 104 of the first substrate 100 is exposed.

As the planarization process is performed, a first division pattern 130 including a first conductive pattern 120 and a first insulation pattern 122 covering a sidewall and a lower surface of the first conductive pattern 120 may be formed in the first trench 110, and a first through via 135 including a second conductive pattern 125 and a second insulation pattern 127 covering a sidewall and a lower surface of the second conductive pattern 125 may be formed in the second trench 115.

In some example embodiments, the first division pattern 130 may have a lattice shape arranged in the first and second directions D1 and D2 in a plan view.

P-type impurities may be doped into a portion or an entire portion of the first substrate 100 to form a p-type well.

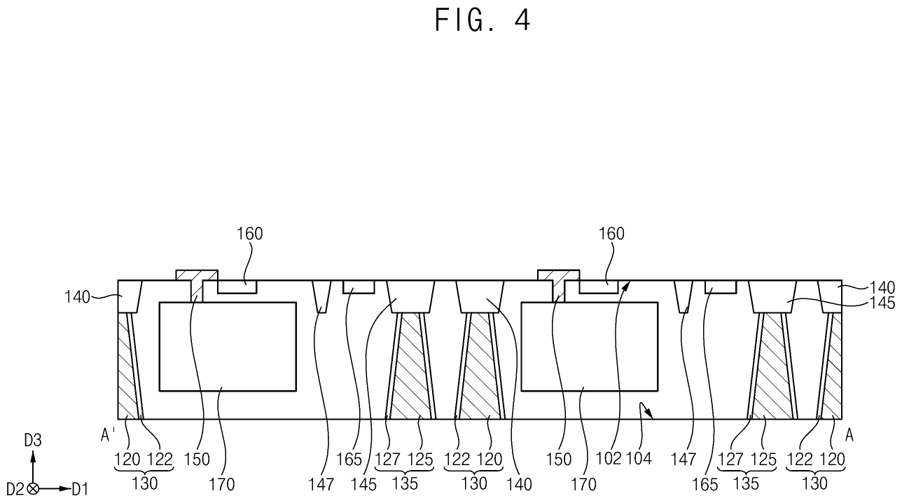

Referring to FIG. 4, after flipping the first substrate 100, a portion of the first substrate 100 adjacent to the first surface 102 of the first substrate 100 may be removed to form third and fourth trenches exposing upper portions of the first and second insulation patterns 122 and 127, respectively, the exposed upper portions of the first and third insulation patterns 122 and 127 may be removed to enlarge the third and fourth trenches, respectively, so that upper surfaces of the first and second conductive patterns 120 and 125 may be exposed, a third insulation layer may be formed on the first surface 102 of the first substrate 100 and the exposed upper surfaces of the first and second conductive patterns 120 and 125, and a planarization process, e.g., a CMP process may be performed on the third insulation layer until the first surface 102 of the first substrate 100 is exposed.

As the planarization process is performed, third and fourth insulation patterns 140 and 145 may be formed in the third and fourth trenches, respectively. In some example embodiments, lower surfaces of the third and fourth insulation patterns 140 and 145 may have areas greater than areas of the first division pattern 130 and the first through via 135, respectively, and the third and fourth insulation patterns 140 and 145 may contact the first division pattern 130 and the first through via 135, respectively.

In some example embodiments, the third insulation pattern 140 may have a lattice shape arranged in the first and second directions D1 and D2 in a plan view. The third insulation pattern 140 may also be referred to as a second division pattern 140, and the first and second division patterns 130 and 140 stacked in the third direction D3 and contacting each other may collectively form a division pattern structure.

When the third and fourth insulation patterns 140 and 145 are formed, a fifth insulation pattern 147 may be further formed at a portion of the first substrate 100 adjacent to the first surface 102.

A first photo detector (PD) 170 may be formed in the first substrate 100, a transfer gate (TG) 150 may be formed on the first surface 102 of the first substrate 100 and extending through a portion of the first substrate 100 adjacent to the first surface 102 thereof, and first and second floating diffusion (FD) regions 160 and 165 may be formed at portions of the first substrate 100 adjacent to the first surface 102 of the first substrate 100.

In some example embodiments, the first PD 170 may be formed by doping n-type impurities into the p-type well of the first substrate 100, and the first PD 170 and the p-type well may collectively form a PN junction diode.

The TG 150 may be formed by forming a fifth trench extending from the first surface 102 of the first substrate 100 downwardly in the third direction D3 to expose an upper surface of the first PD 170 and filling the fifth trench. In some example embodiments, the TG 150 may include a buried portion, which may fill the fifth trench and contact the upper surface of the first PD 170, and a protrusion portion, which may be disposed on the buried portion, have an upper surface higher than the first surface 102 of the first substrate 100, and contact the first surface 102 of the first substrate 100.

The first and second FD regions 160 and 165 may be formed by doping, e.g., n-type impurities into a portion of the first substrate 100 adjacent to the first surface 102 of the first substrate 100. The first FD region 160 may be formed to be adjacent to the TG 150, and the second FD region 165 may be formed to be adjacent to the fourth insulation pattern 145.

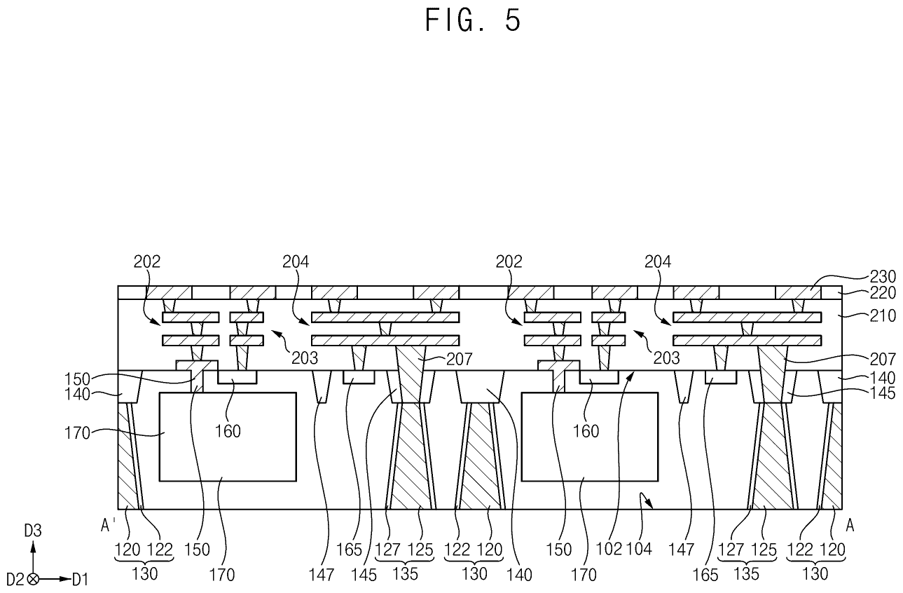

Referring to FIG. 5, first to third wiring structures 202, 203 and 204 may be formed on the first surface 102 of the first substrate 100 to be electrically connected to the TG 150, the first and second FD regions 160 and 165 and the first through via 135, a first insulating interlayer 210 may be formed to cover the first to third wiring structures 202, 203 and 204, and a first bonding layer 220 containing first bonding pads 230 may be formed on the first insulating interlayer 210.

In some example embodiments, each of the first to third wiring structures 202, 203 and 204 may include contact plugs, wirings and vias. For example, the third wiring structure 204 may include a second through via 207 extending through a lower portion of the first insulating interlayer 210 and the fourth insulation pattern 145 to contact an upper surface of the first through via 135.

In some example embodiments, the first wiring structure 202 may contact the TG 150 to be electrically connected thereto, the second wiring structure 203 may contact the upper surface of the first FD region 160 to be electrically connected thereto, and the third wiring structure 204 may contact the upper surfaces of the first through via 135 and the second FD region 165 to be electrically connected thereto.

Each of the first bonding pads 230 may contact one of the first to third wiring structures 202, 203 and 204 to be electrically connected thereto.

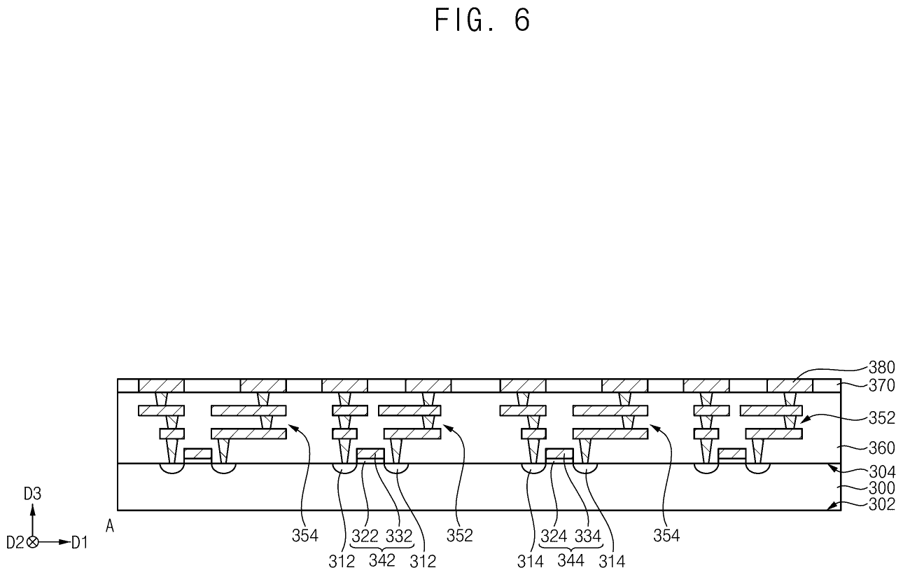

Referring to FIG. 6, first and second transistors may be formed on a second surface 304 of a second substrate 300 including a first surface 302 and the second surface 304 opposite to each other in the third direction D3, fourth and fifth wiring structures 352 and 354 may be formed to be electrically connected to the first and second transistors, respectively, a second insulating interlayer 360 may be formed on the second surface 304 of the second substrate 300, and a second bonding layer 370 including second bonding pads 380 may be formed in the second insulating interlayer 360.

The first transistor may include a first gate structure 342 having a first gate electrode 332 and a first gate insulation pattern 322, and first source/drain regions 312 at portions of the second substrate 300 adjacent to the first gate structure 342. The second transistor may include a second gate structure 344 having a second gate electrode 334 and a second gate insulation pattern 324, and second source/drain regions 314 at portions of the second substrate 300 adjacent to the second gate structure 344.

FIG. 6 shows the first and second transistors, however, the inventive concepts are not limited thereto, and additional transistors may be included on the second surface 304.

In some example embodiments, each of the fourth and fifth wiring structures 352, 354 may include contact plugs, wirings, vias, etc.

In some example embodiments, the fourth wiring structure 352 may be electrically connected to the first transistor, and the fifth wiring structure 354 may be electrically connected to the second transistor.

Each of the second bonding pads 380 may contact one of the fourth and fifth wiring structures 352 and 354 to be electrically connected thereto.

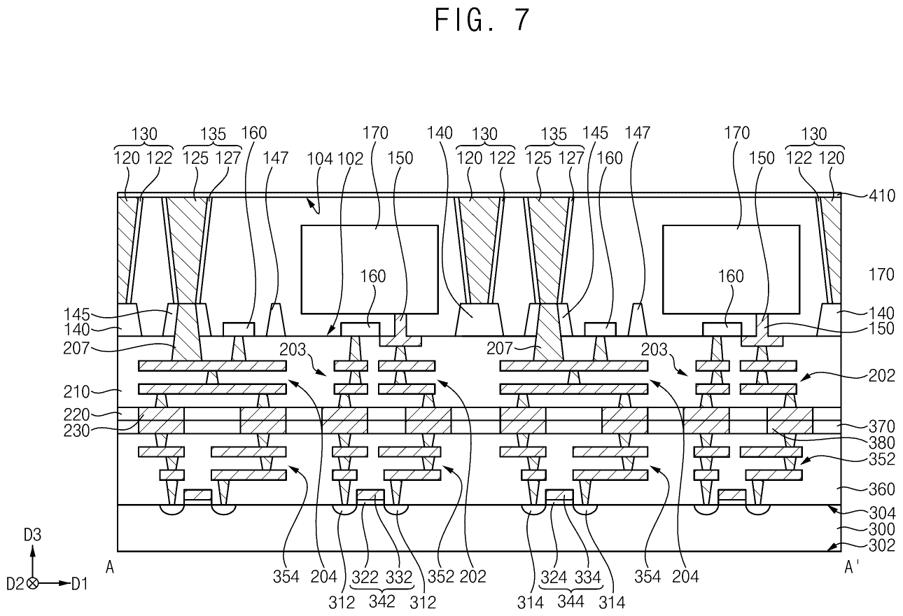

Referring to FIG. 7, after flipping the first substrate 100, the first bonding layer 220 on the first substrate 100 and the second bonding layer 370 on the second substrate 300 may contact each other so that the first and second substrates 100 and 300 may be bonded to each other.

The first bonding pads 230 in the first bonding layer 220 may contact the second bonding pads 380, respectively, in the second bonding layer 370.

A first buffer layer 410 include an oxide, e.g., silicon oxide may be formed on the second surface 104 of the first substrate 100, the first division pattern 130 and the first through via 135.

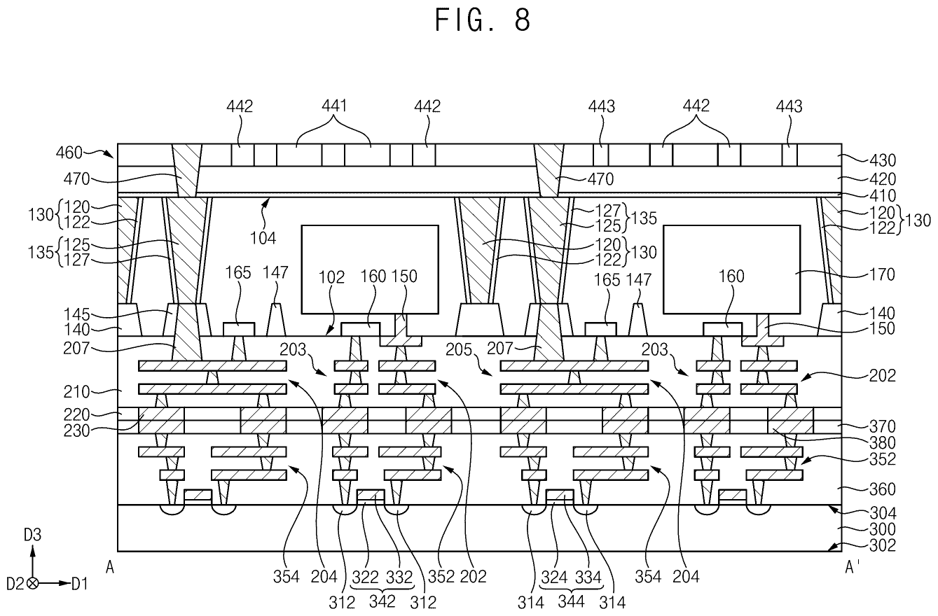

Referring to FIG. 8, a spacer layer 420 may be formed on the first buffer layer 410, and a nano-prism 460 may be formed on the spacer layer 420.

The spacer layer 420 may include an oxide, e.g., silicon oxide, and in some example embodiments, the spacer layer 420 may be merged to the first buffer layer 410.

Referring to FIG. 8 together with FIG. 2, the nano-prism 460 may be formed by forming a first low refractive layer 430 including a low refractive material, e.g., silicon oxide on the spacer layer 420, partially etching the first low refractive layer 430 to form first to fourth holes each of which may expose an upper surface of the spacer layer 420, forming a high refractive layer including a high refractive material, e.g., titanium oxide on the spacer layer 420 and the first low refractive layer 430 to fill the first to fourth holes, and performing a planarization process, e.g., a CMP process on the high refractive layer to form first to fourth high refractive patterns 441, 442, 443 and 444 in the first to fourth holes, respectively. The first to fourth high refractive patterns 441, 442, 443 and 444 may also be referred to as first to fourth nano-post patterns 441, 442, 443 and 444, respectively.

In some example embodiments, each of the first to fourth nano-post patterns 441, 442, 443 and 444 may have a pillar shape, and may have a shape, e.g., a circle, an ellipse, a polygon, a polygon with rounded corners, etc., in a plan view. The first to fourth nano-post patterns 441, 442, 443 and 444 may have first to fourth diameters D1, D2, D3 and D4, respectively, in the vertical direction, which may have decreasing values in this order.

In some example embodiments, the first to fourth nano-post patterns 441, 442, 443 and 444 may have various layouts in the horizontal direction. For example, the first, second and fourth nano-post patterns 441, 442 and 444 may be arranged in a first unit pixel region, the second and third nano-post patterns 442 and 443 may be arranged in a second unit pixel region, and the second, third and fourth nano-post patterns 442, 443 and 444 may be arranged in a third unit pixel region. In some example embodiments, the first to third unit pixel regions may be regions that may filter a red light R, a green light G and a blue light B, respectively, however, the inventive concepts are not limited thereto.

A third through via 470 may be formed through the first low refractive layer 430, the spacer layer 420 and the first buffer layer 410 to contact an upper surface of the first through via 135. The second through via 207, the first through via 135 and the third through via 470 sequentially stacked in the third direction D3 may collectively form a through via structure.

Referring back to FIGS. 1 and 2, a first electrode layer 510 including a first electrode 520, a second PD 530, a second electrode 550 and a first protective layer 560 may be sequentially stacked on the nano-prism 460 and the third through via 470.

In some example embodiments, the first electrode 520 may contact an upper surface of the third through via 470.

In some example embodiments, the second PD 530 may be formed by an evaporation process, and thus an organic photo detector may be formed. Alternatively, the second PD 530 may be formed by a spin coating process, and thus a quantum dot (PD) photo detector may be formed.

By the above processes, the manufacturing of the image sensor may be completed.

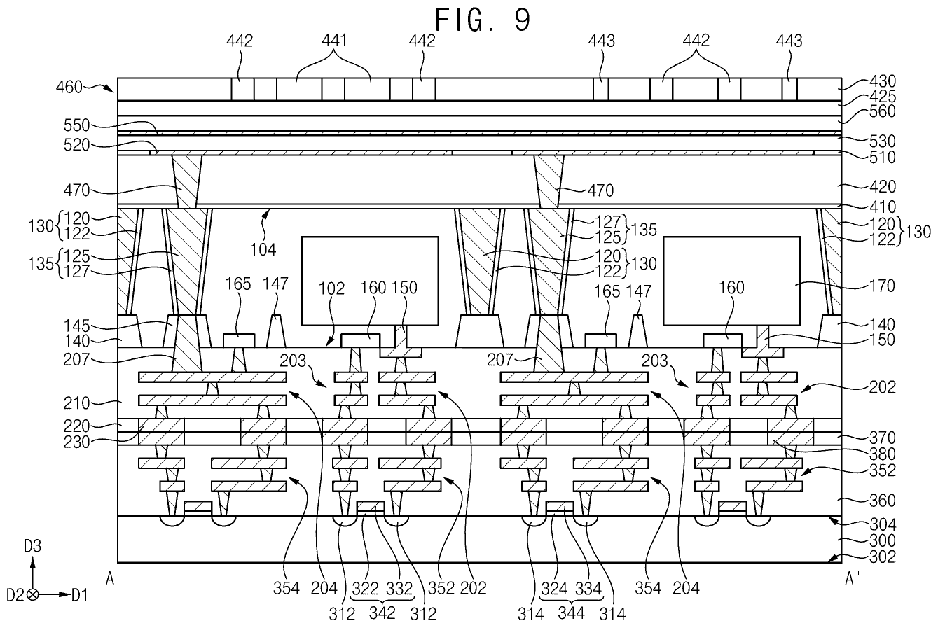

FIGS. 9 to 12 are cross-sectional views illustrating image sensors in accordance with some example embodiments, which may correspond to FIG. 1.

Referring to FIG. 9, a second photo detector structure including the first electrode layer 510, the second PD 530, the second electrode 550 and the first protective layer 560, the spacer layer 425 and the nano-prism 460 may be sequentially stacked in the third direction D3 on the spacer layer 420.

In some example embodiments as shown in FIG. 9, the spacer layer 420 may be disposed between the first buffer layer 410 and the second photo detector structure, however, the inventive concepts are not limited thereto. In some example embodiments, the spacer layer 420 may not be formed, and the first electrode layer 510 may be directly disposed on the upper surface of the first buffer layer 410.

A light incident on the upper surface of the image sensor may be divided into a plurality of lights having different colors through the nano-prism 460, each of the divided lights may pass through the spacer layer 425, the second photo detector structure, the first buffer layer 410 and the upper portion of the first substrate 100 to be condensed into the first PD 170.

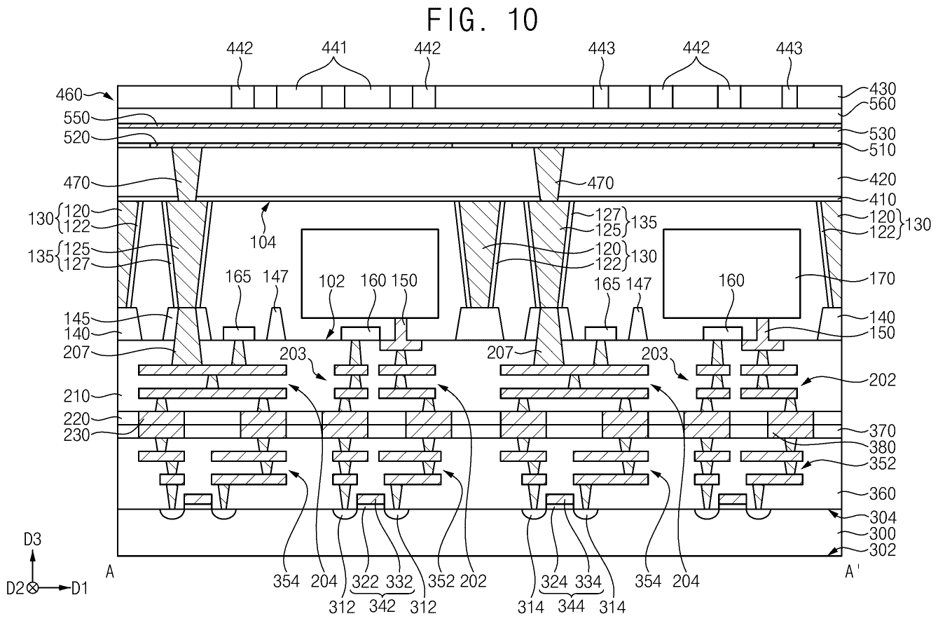

Referring to FIG. 10, the image sensor may be the same or substantially the same as or similar to that of FIG. 9, except for not including the spacer layer 425 on the second photo detector structure.

Even though the image sensor does not include the spacer layer 425 on the second photo detector structure, the first protective layer 560 of the second photo detector structure, which may include a material having a refractive index less than that of the nano-post pattern, e.g., aluminum oxide, may function as the spacer layer 420.

The nano-prism 460 may be disposed on the second photo detector structure, and thus there is a sufficiently large distance through which each of the divided lights in the nano-prism 460 may be condensed into the first PD 170 by the second photo detector structure or the spacer layer 420 on the first buffer layer 410.

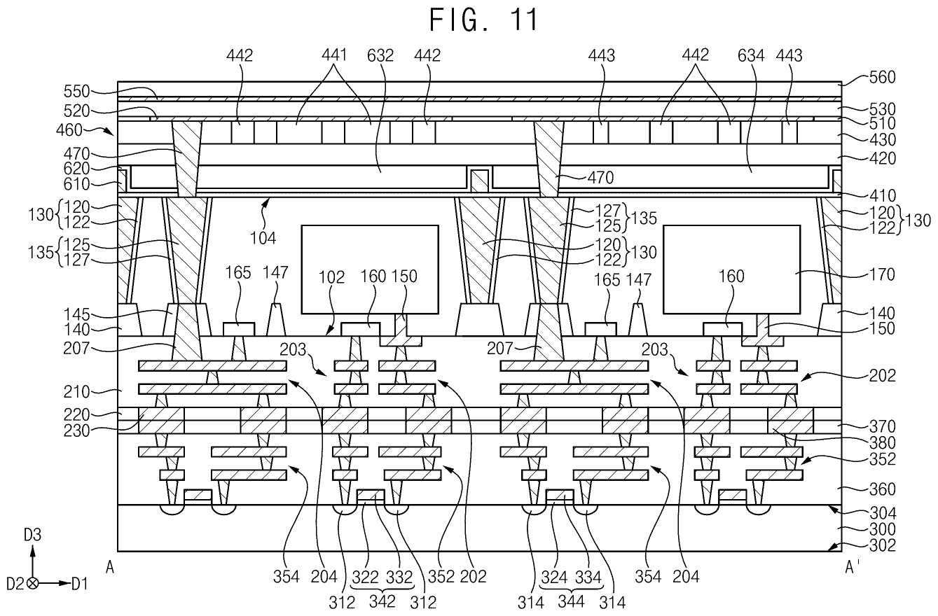

Referring to FIG. 11, the image sensor may further include a color filter array layer between the first buffer layer 410 and the spacer layer 420.

The color filter array layer may include a plurality of color filters, e.g., first, second and third color filters, separated from each other by the interference blocking structure 610 on a portion of the first buffer layer 410 overlapping the division pattern structure in the first substrate 100 in the third direction D3. FIG. 11 includes a first color filter 632 and a second color filter 634.

The first color filter 632, the second color filter 634 and a third color filter may be a red color filter, a green color filter and a blue color filter, respectively, however, the inventive concepts are not limited thereto.

The interference blocking structure 610 may serve as a barrier for limiting and/or preventing a light incident onto a unit pixel region from moving into another unit pixel region so as to block interference between neighboring unit pixel regions.

The interference blocking structure 610 may include a metal nitride, e.g., titanium nitride, or a metal, e.g., tungsten. In some example embodiments, the interference blocking structure 610 may include a first interference blocking pattern and a second interference blocking pattern stacked in the third direction D3. The first interference blocking pattern may include a metal nitride, e.g., titanium nitride, and the second interference blocking pattern may include a metal, e.g., tungsten.

A second protective layer 620 may be further disposed on an upper surface of the first buffer layer 410 and an upper surface and a sidewall of the interference blocking structure 610, and the color filter array layer may be disposed on the second protective layer 620. The second protective layer 620 may include a metal oxide, e.g., aluminum oxide.

The image sensor may further include the color filter array layer between the first PD 170 and the nano-prism 460, and thus color division function with respect to a visible ray may be enhanced, and cross-talk between neighboring unit pixel regions may be improved.

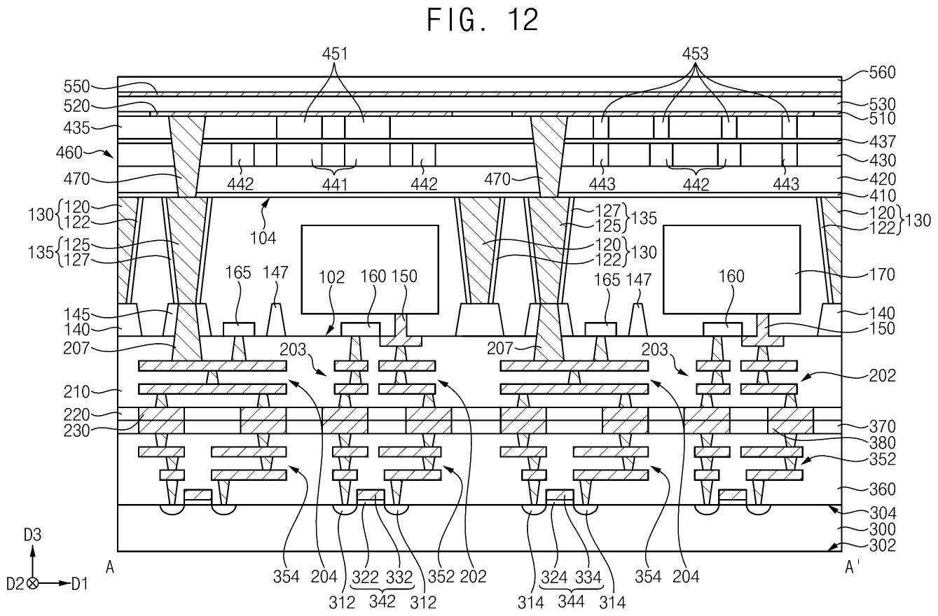

Referring to FIG. 12, the nano-prism 460 may include the first low refractive layer 430, a second buffer layer 437 and a second low refractive layer 435 stacked in the third direction D3.

In some example embodiments, the second low refractive layer 435 may include the same or substantially the same material as the first low refractive layer 430, and may have the same or substantially the same thickness in the third direction D3 as the first low refractive layer 430, however, the inventive concepts are not limited thereto.

The second buffer layer 437 may include an oxide, e.g., silicon oxide.

For example, fifth to eighth nano-post patterns may be disposed in the second low refractive layer 435, and fifth and sixth nano-post patterns 451 and 453 are shown in FIG. 12. FIG. 12 shows that the fifth nano-post pattern 451 has a diameter the same or substantially the same as that of the first nano-post pattern 441, and the sixth nano-post pattern 453 has a diameter the same or substantially the same as that of the third nano-post pattern 443, however, the inventive concepts are not limited thereto.

As the nano-prism 460 includes the nano-post patterns in the first and second low refractive layers 430 and 435, respectively, stacked in the third direction D3, and thus, when compared to the nano-prism 460 including the nano-post patterns only in a single low refractive layer, a degree of freedom of designing layouts of the nano-post patterns having different diameters may increase.

As described above, although the present inventive concepts have been described with reference to some example embodiments, those skilled in the art will readily appreciate that many modifications are possible in the some example embodiments without materially departing from the novel teachings and advantages of the present inventive concepts.

What is claimed is:

1. An image sensor comprising:
a first photo detector (PD) in a substrate, the first PD being configured to absorb a visible ray;
a spacer layer on the substrate;
a nano-prism on the spacer layer; and
a second PD structure on the nano-prism, the second PD structure being configured to absorb an infrared ray,
wherein the nano-prism is configured to divide an incident light into a plurality of lights by color, and the spacer layer is configured to condense each of the plurality of lights onto the first PD, and
wherein the nano-prism includes
a first low refractive layer, and
a first nano-post pattern extending through the first low refractive layer.

2. The image sensor of claim 1, further comprising a plurality of nano-post patterns spaced apart from each other in a horizontal direction in the first low refractive layer, the first nano-post pattern being one of the plurality of nano-post patterns,
wherein diameters of nano-post patterns from among the plurality of nano-post patterns are different from each other.

3. The image sensor of claim 1, wherein the first low refractive layer includes silicon oxide, and the first nano-post pattern includes titanium oxide.

4. The image sensor of claim 1, wherein the nano-prism includes:
a second low refractive layer on the first low refractive layer; and
a second nano-post pattern in the second low refractive layer.

5. The image sensor of claim 1, wherein the spacer layer includes silicon oxide.

6. The image sensor of claim 1, wherein the spacer layer has a thickness of about 200 nm to about 1000 nm.

7. The image sensor of claim 1, wherein the second PD structure includes:
a first electrode;
a second PD on the first electrode; and
a second electrode on the second PD.

8. The image sensor of claim 7, wherein the second PD includes an organic photo detector, and the organic photo detector is configured to absorb a near infrared (NIR) ray.

9. The image sensor of claim 7, wherein the second PD includes a quantum dot (QD) photo detector, and the QD photo detector is configured to absorb a short-wave infrared (SWIR) ray.

10. The image sensor of claim 7, further comprising:
a through via structure extending through the substrate, the spacer layer and the nano-prism, the through via structure contacting the first electrode;
a wiring structure electrically connected to the through via structure; and
a floating diffusion (FD) region in the substrate, the FD region being electrically connected to the wiring structure.

11. The image sensor of claim 1, further comprising a color filter array layer between the substrate and the spacer layer.

12. An image sensor comprising:
a first photo detector (PD) in a substrate, the first PD being configured to absorb a visible ray;
a second PD structure on the substrate, the second PD structure being configured to absorb an infrared ray; and
a nano-prism on the second PD structure, the nano-prism including
a low refractive layer, and
nano-post patterns in the low refractive layer, the nano-post patterns being spaced apart from each other in a horizontal direction, and diameters of the nano-post patterns being different from each other.

13. The image sensor of claim 12, wherein the low refractive layer includes silicon oxide, and the nano-post patterns include titanium oxide.

14. The image sensor of claim 12, further comprising a spacer layer between the second PD structure and the nano-prism, the spacer layer including silicon oxide.

15. The image sensor of claim 12, further comprising a spacer layer between the substrate and the second PD structure, the spacer layer including silicon oxide.

16. The image sensor of claim 12, wherein the second PD structure includes:
a first electrode;
a second PD on the first electrode; and
a second electrode on the second PD.

17. The image sensor of claim 16, wherein the second PD includes a quantum dot (QD) photo detector, and the QD photo detector is configured to absorb a short-wave infrared (SWIR) ray.

18. An image sensor comprising:
first and second wiring structures under a substrate;
a first floating diffusion (FD) region at a lower portion of the substrate, the first FD region being electrically connected to the first wiring structure;
a first photo detector (PD) in the substrate, the first PD being configured to absorb a visible ray;
a second FD region at the lower portion of the substrate, the second FD region being electrically connected to the second wiring structure;
a spacer layer on the substrate;
a nano-prism on the spacer layer;
a second PD structure on the nano-prism, the second PD being configured to absorb an infrared ray; and
a through via structure extending through the substrate, the spacer layer and the nano-prism, the through via structure being electrically connected to the second wiring structure and the second PD structure.

19. The image sensor of claim 18, wherein the nano-prism includes:
a low refractive layer; and
nano-post patterns in the low refractive layer, the nano-post patterns being spaced apart from each other in a horizontal direction, and diameters of the nano-post patterns being different from each other.

20. The image sensor of claim 18, wherein the second PD structure includes:
a first electrode;
a second PD on the first electrode; and
a second electrode on the second PD,
wherein the through via structure is electrically connected to the first electrode.
